(19) United States
(12) Patent Application Publication
(10) Pub. No.: US 2019/0044481 A1
(43) Pub. Date: Feb. 7, 2019

(54) ARCHITECTURE FOR HIGH-BANDWIDTH POWER SUPPLY TO POWER AMPLIFIER (PA) DISTRIBUTION NETWORK

(71) Applicant: QUALCOMM Incorporated, San Diego, CA (US)

(72) Inventors: Antonino SCUDERI, San Diego, CA (US); Thomas MARRA, San Diego, CA (US)

(21) Appl. No.: 15/960,191

(22) Filed: Apr. 23, 2018

Related U.S. Application Data
(60) Provisional application No. 62/541,215, filed on Aug. 4, 2017.

(51) Int. Cl. H03F 1/02; H03F 3/21; H03F 3/19; H03F 1/26

(52) U.S. Cl. CPC H03F 1/0216; H04B 1/40; H03F 3/19; H03F 1/26; H03F 2200/231; H03F 2200/102; H03F 2200/111; H03F 2200/165; H03F 2200/451; H03F 2200/267; H03F 2200/255; H03F 2200/213; H03F 2203/21112; H03F 2203/21136; H03F 2203/21181; H03F 3/211

(57) ABSTRACT

A power supply to power amplifier (PA) distribution network may include a first power supply. The PA distribution network may further include at least one power amplifier. The power amplifier may be coupled to the first power supply. The power amplifier may include a driver stage and a power stage. The power amplifier may be coupled to the first power supply via a first switch.

### CROSS-REFERENCE TO RELATED APPLICATION

The present application claims the benefit of U.S. Provisional Patent Application No. 62/541,215, filed on Aug. 4, 2017, and titled “ARCHITECTURE FOR HIGH-BANDWIDTH POWER SUPPLY TO POWER AMPLIFIER (PA) DISTRIBUTION NETWORK,” the disclosure of which is expressly incorporated by reference herein in its entirety.

### BACKGROUND

### Field

The present disclosure generally relates to a power supply to power amplifier distribution network. More specifically, the present disclosure relates to supplying power to a power amplifier network.

### Background

Electronic amplifiers increase power and/or an amplitude of various electronic signals. Most electronic amplifiers operate by using power from a power supply. These electronic amplifiers may operate by controlling an output signal to match the shape of an input signal, while providing a higher amplitude signal.

One widely used type of electronic amplifier is a power amplifier (PA). A power amplifier is a versatile device used in various applications to meet design specifications for signal conditioning, special transfer functions, analog instrumentation, and analog computation, among others. Power amplifiers are often used in wireless applications, and may employ radio frequency (RF) amplifier designs for use in an RF range of an electromagnetic spectrum. An RF power amplifier is a type of electronic amplifier used to convert a low-power RF signal into a signal of significant power, for example, for driving an antenna of a transmitter. RF power amplifiers are also used to increase the range of a wireless communication system by increasing the output power of a transmitter.

An envelope modulator may drive multiple power amplifiers and may support wideband modulation. A capacitive load of the envelope modulator, however, negatively affects wideband modulation as well as modulator stability and efficiency.

### SUMMARY

A power supply to power amplifier (PA) distribution network may include a first power supply. The PA distribution network may further at least one power amplifier. The power amplifier may be coupled to the first power supply. The power amplifier may include a driver stage and a power stage. The power amplifier may be coupled to the first power supply via a first switch.

A method of supplying power to a power amplifier (PA) network may include coupling at least one of a driver stage and/or a power stage of a first PA of the PA network to a first power supply when the first PA is active. The method may further include decoupling at least one of the driver stage and/or the power stage of the first PA from the first power supply when the first PA is inactive.

A power supply to power amplifier (PA) distribution network may include a first means for supplying power. The PA distribution network may further include at least one power amplifier. The power amplifier may be coupled to the first power supply means. The power amplifier may include a driver stage and a power stage. The power amplifier may be coupled to the first power supply means via a first switch.

Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 shows a block diagram of a wireless communication device.

FIG. 2 shows a block diagram of a conventional power amplifier (PA) network.

FIGS. 3A and 3B show block diagrams of power supply to power amplifier (PA) distribution networks according to aspects of the present disclosure.

FIG. 4 is a process flow diagram illustrating a method of supplying power to a power supply to power amplifier (PA) distribution network according to aspects of the present disclosure.

FIG. 5 is a block diagram showing an exemplary wireless communication system in which a configuration of the disclosure may be advantageously employed.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR”, and the use of the term “or” is intended to represent an “exclusive OR”. As described herein, the term “exemplary” used throughout this description means “serving as an example, instance, or illustration,” and should not necessarily be construed as preferred or advantageous over other exemplary configurations. The term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Radio frequency (RF) amplifier design is an immensely complex process. An RF power amplifier is a type of electronic amplifier used to convert a low-power RF signal into a signal of significant power, for example, for driving an antenna of a transmitter. RF power amplifiers are also used to increase the range of a wireless communication system by increasing the output power of a transmitter. Increasing the efficiency of a transmitter may involve envelope tracking (ET). Envelope tracking is a technique where an envelope modulator continuously adjusts the power supply voltage applied to the RF power amplifier. Adjusting the power supply voltage applied to the RF power amplifier is performed to ensure that the RF power amplifier is operating at a peak efficiency for an amount of power specified at each instant of data transmission.

An envelope modulator (e.g., an envelope tracker) may be implemented to drive multiple RF power amplifiers for supporting wide bandwidth modulation (e.g., amplitude modulation). The performance of the envelope modulator, however, is limited by its capacitive load. This capacitive load may negatively affect wide bandwidth modulation, modulator efficiency, and modulator stability. By contrast, RF power amplifiers rely on capacitance for stable operation and good noise performance. In particular, an RF power amplifier supply bypass capacitor is the main capacitive load of the envelope modulator, and it is difficult to reduce the capacitive load to assure performance and stability of the RF power amplifier. Hence, a noise level of the envelope modulator is a trade-off for better efficiency, as an increased signal bandwidth affects the ability of the envelope modulator to filter noise due to its direct impact on the envelope modulation.

Various solutions exist for mitigating the capacitive load from negatively affecting the envelope modulator. These solutions include reducing the power amplifier supply filter, increasing the number of envelope modulators, and noise reduced filtering by adoption of higher isolation filters. These solutions, however, increase the cost of the envelope modulator, and involve undesirable tradeoffs regarding RF power amplifier performance, stability, availability, and insertion loss.

Aspects of the present disclosure involve an improved architecture for supplying power to an RF power amplifier network. The improved architecture may include any combination of low-band, mid-band, and high-band power amplifiers. For example, the RF power amplifier network may be implemented through cascaded amplifiers, which may include a first stage (e.g., a driver amplifier (DA) stage) followed by a final stage (e.g., a power stage). According to an aspect, the improved architecture disconnects off-mode power amplifiers from the modulator distribution line by disconnecting a driver stage of the power amplifier by adding a series switch on the driver stage path. The series switch also couples/decouples a capacitive load of a supply filter to/from the distribution line. A series resistance of the switch may be exploited to stabilize resistance for envelope tracking, driver amplifier, and power amplifier modulation. Additional aspects may involve disconnecting the final stage. Yet another aspect involves disconnecting the first stage and the final stage. Disconnecting the driver amplifier is possible due to limited current capability.

According to an aspect, when at least one of a driver stage and/or power stage of a low-band power amplifier, mid-band power amplifier, or high-band power amplifier is decoupled from a transmission line, at least one other driver stage and/or power stage of another low-band power amplifier, mid-band power amplifier, or high-band power amplifier may be coupled to the transmission line. For example, in a power supply-to-PA distribution network with one low-band power amplifier, one mid-band power amplifier, and one high-band power, if a driver stage of the low-band amplifier is decoupled from the transmission line, then at least one driver stage of the mid-band or high-band power amplifier may be coupled to the transmission line. In this way, a power amplifier can be coupled to the transmission line while another power amplifier is decoupled from the transmission line.

According to additional aspects, all capacitive loads for on-mode functionality may be added after the series switch. Thus, the capacitive loads can be selectively removed from the transmission line, thereby reducing the capacitance seen by the envelope tracking power supply. For example, a resistor-capacitor (RC) element, such as a noise notch and/or a programmable bypass capacitor, may be added after the series switch. The programmable bypass capacitor may improve or even optimize the supply filter based on a number of power amplifiers in the network and a device's parasitic compensation for increasing power amplifier stability under mismatch.

According to additional aspects of the present disclosure, the reconfigurable envelope distribution network may also disconnect the driver amplifier from the modulation distribution network so an alternate source of power can be provided. A second series switch may supply the driver amplifier with a constant voltage supply instead of the envelope tracked power supply. This may be particularly useful for very wide bandwidth signals to improve noise and linearity.

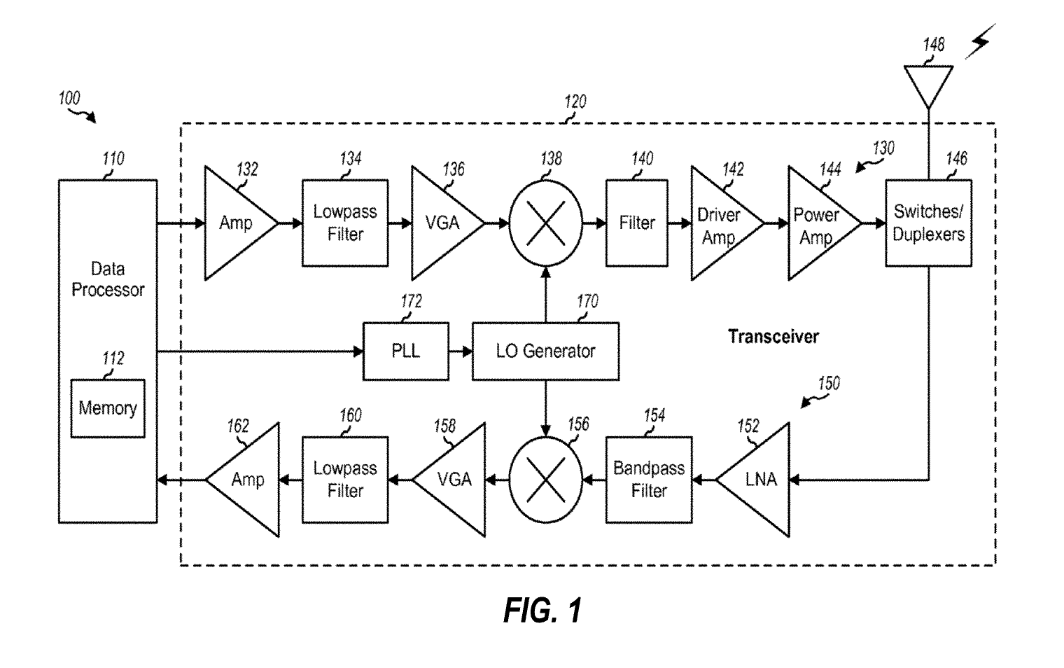

FIG. 1 shows a block diagram of an exemplary design of a wireless communication device or wireless communication device 100 that may include the improved PA network. In this exemplary design, the wireless communication device 100 includes a data processor 110 and a transceiver 120. The transceiver 120 includes a transmitter 130 and a receiver 150 that support bi-directional wireless communication. In general, the wireless communication device 100 may include any number of transmitters and any number of receivers for any number of communication systems and any number of frequency bands.

In the transmit path, the data processor 110 processes data to be transmitted and provides an analog output signal to the transmitter 130. Within the transmitter 130, the analog output signal is amplified by an amplifier (Amp) 132, filtered by a low pass filter 134 to remove images caused by digital-to-analog conversion, amplified by a VGA 136, and upconverted from baseband to radio frequency (RF) by a mixer 138. The upconverted signal is filtered by a filter 140, further amplified by a driver amplifier 142 and a power amplifier 144, routed through switches/duplexers 146, and transmitted via an antenna 148.

In the receive path, the antenna 148 receives signals from base stations and/or other transmitter stations and provides a received signal, which is routed through the switches/duplexers 146 and provided to the receiver 150. Within the receiver 150, the received signal is amplified by a low noise amplifier (LNA) 152, filtered by a bandpass filter 154, and downconverted from RF to baseband by a mixer 156. The downconverted signal is amplified by a VGA 158, filtered by a low pass filter 160, and amplified by an amplifier 162 to obtain an analog input signal, which is provided to the data processor 110.

FIG. 1 shows the transmitter 130 and the receiver 150 implementing a direct-conversion architecture, which frequency converts a signal between RF and baseband in one stage. The transmitter 130 and/or the receiver 150 may also implement a super-heterodyne architecture, which frequency converts a signal between RF and baseband in multiple stages. A local oscillator (LO) generator 170 generates and provides transmit and receive LO signals to the mixer 138 and the mixer 156, respectively. A phase locked loop (PLL) 172 receives control information from the data processor 110 and provides control signals to the LO generator 170 to generate the transmit and receive LO signals at the proper frequencies.

FIG. 1 shows an exemplary transceiver design. In general, the conditioning of the signals in the transmitter 130 and the receiver 150 may be performed by one or more stages of amplifier, filter, mixer, etc. These circuits may be arranged differently from the configuration shown in FIG. 1. Furthermore, other circuits not shown in FIG. 1 may also be used in the transmitter and the receiver. For example, matching circuits may be used to match various active circuits in FIG. 1. Some circuits in FIG. 1 may also be omitted. The transceiver 120 may be implemented on one or more analog integrated circuits (ICs), radio frequency ICs (RFICs), mixed-signal ICs, etc. For example, the amplifier 132 through the power amplifier 144 in the transmitter 130 may be implemented on an RFIC. The driver amplifier 142 and the power amplifier 144 may also be implemented on another IC external to the RFIC.

The data processor 110 may perform various functions for the wireless communication device 100, e.g., processing for transmitted and received data. A memory 112 may store program codes and data for the data processor 110. The data processor 110 may be implemented on one or more application specific integrated circuits (ASICs) and/or other ICs.

As shown in FIG. 1, a transmitter and a receiver may include various amplifiers. Each amplifier at RF may have input impedance matching and output impedance matching, which are not shown in FIG. 1 for simplicity.

According to aspects of the present disclosure, a power supply to power amplifier distribution network may include a power supply and multiple power amplifiers. Each power amplifier may include a driver stage and a power stage, and may be coupled to the power supply. Each power amplifier may be further coupled to the power supply through a switch.

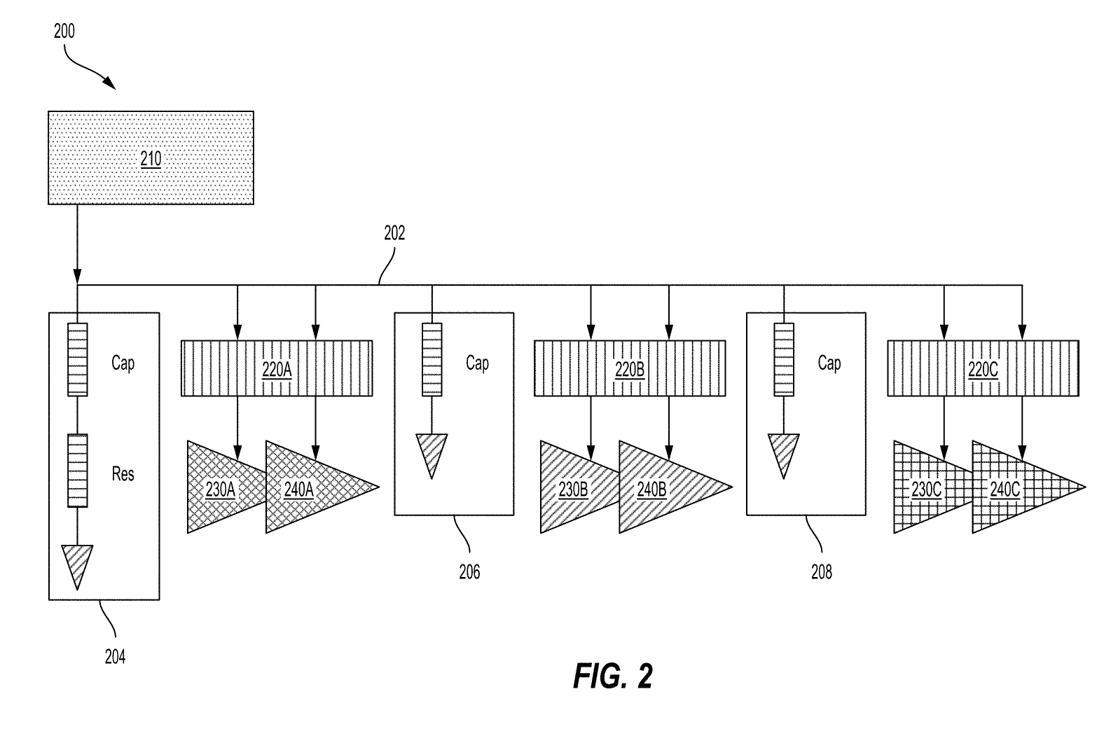

FIG. 2 shows a block diagram of a conventional power amplifier (PA) network 200. The PA network 200 may include an envelope tracking (ET) modulator 210 coupled to a low-band supply filter 220A, a mid-band supply filter 220B, and a high-band supply filter 220C through a transmission line 202. The low-band supply filter 220A may be coupled to a low-band driver amplifier 230A and a low-band power amplifier 240A. The mid-band supply filter 220B may be coupled to a mid-band driver amplifier 230B and a mid-band power amplifier 240B. The high-band supply filter 220C may be coupled to a high-band driver amplifier 230C and a high-band power amplifier 240C. Each of the supply filters includes a stabilization resistor.

The PA network 200 may further include a stabilizing circuit 204 (e.g., a resistor-capacitor (RC) snubber), a first noise filter 206 (e.g., a capacitor), and a second noise filter 208. The stabilizing circuit 204 may be coupled to the transmission line 202 before the low-band supply filter 220A. The first noise filter 206 may be coupled between the low-band supply filter 220A and the mid-band supply filter 220B. The second noise filter 208 may be coupled between the mid-band supply filter 220B and the high-band supply filter 220C.

The performance of the envelope tracking modulator 210 is limited by its capacitive load. This capacitive load may negatively affect wide bandwidth modulation, modulator efficiency, and modulator stability. By contrast, RF power amplifiers rely on capacitance for stable operation and good noise performance. In particular, an RF power amplifier supply bypass capacitor is the main capacitive load of the envelope tracking modulator 210. It is difficult to reduce the capacitive load to assure performance and stability of the RF power amplifier. Hence, a noise level of the envelope tracking modulator 210 is a trade-off for better efficiency, as an increased signal bandwidth affects the ability of the envelope tracking modulator 210 to filter noise due to its direct impact on the envelope modulation.

Various solutions exist for mitigating the capacitive load from negatively affecting the envelope modulator. These solutions include reducing the power amplifier supply filter, increasing the number of envelope modulators, and noise reduced filtering by adoption of higher isolation filters. These solutions, however, increase the cost of the envelope modulator, and involve undesirable tradeoffs regarding RF power amplifier performance, stability, availability, and insertion loss.

Aspects of the present disclosure involve an improved architecture for supplying power to an RF power amplifier network. An improved architecture may include any combination of low-band, mid-band, and high-band power amplifiers. For example, the RF power amplifier network may be implemented through cascaded amplifiers, which may include a first stage (e.g., a driver amplifier (DA) stage) followed by a final stage (e.g., a power stage). According to an aspect, an improved architecture disconnects off-mode power amplifiers from the modulator distribution line by disconnecting a driver stage of the power amplifier by adding a series switch on the driver stage path. The series switch also couples/decouples a capacitive load of a supply filter to/from the distribution line. Additional aspects may involve disconnecting the final stage. Yet another aspect involves disconnecting the first stage and the final stage.

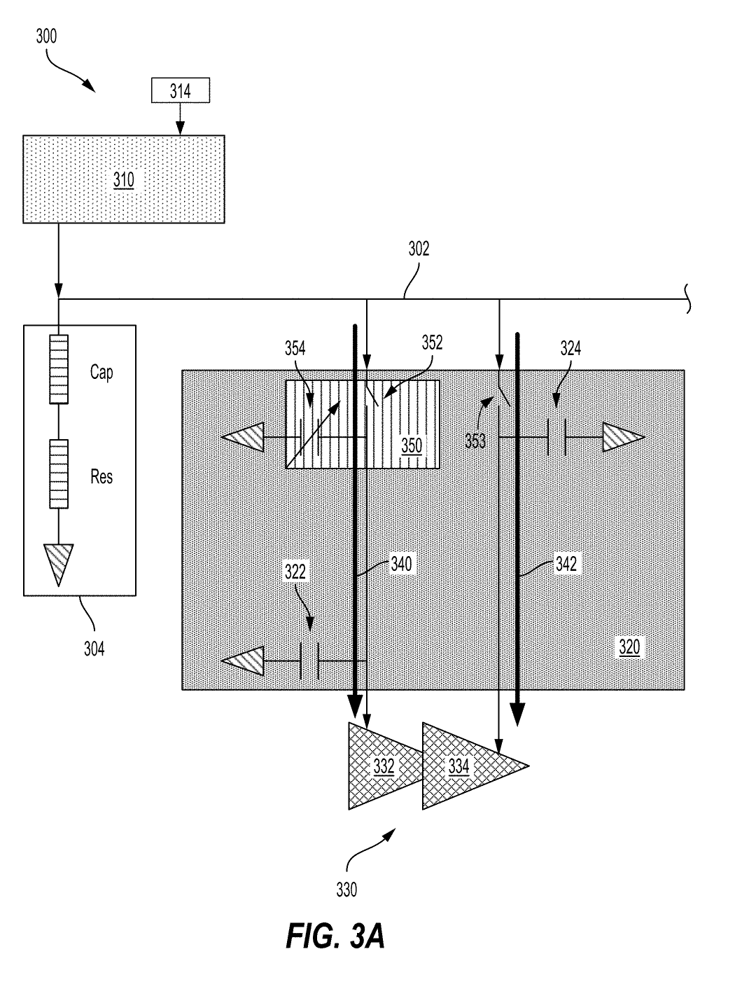

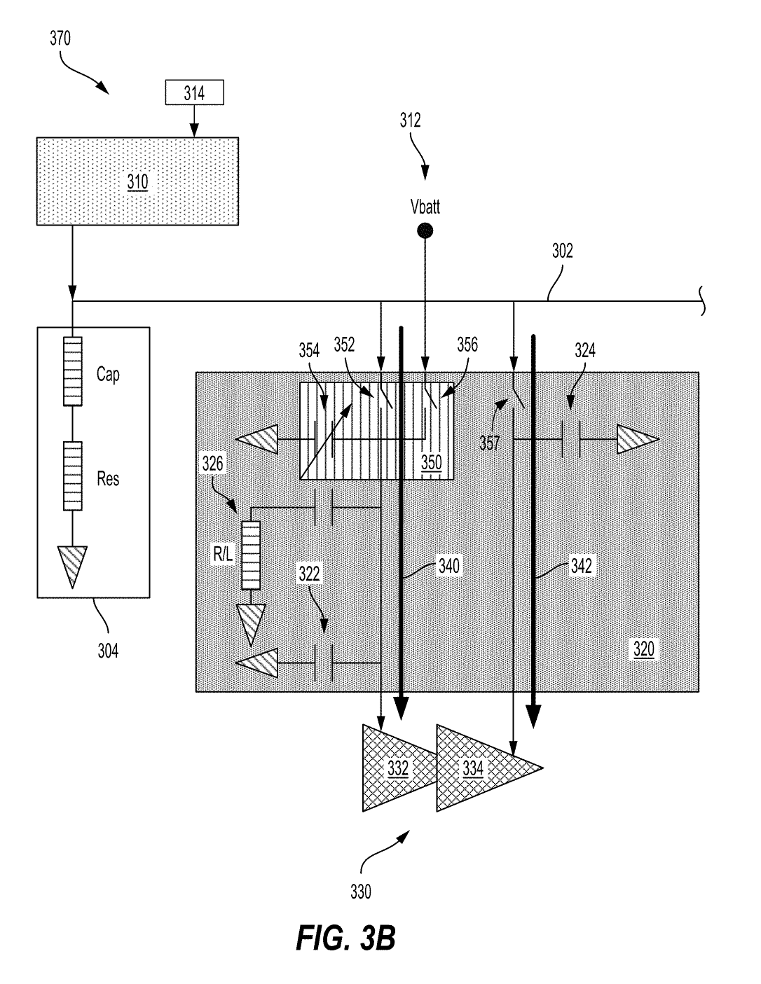

FIGS. 3A and 3B show block diagrams of power supply to power amplifier (PA) distribution networks according to aspects of the present disclosure.

Referring to FIG. 3A, a power supply-to-PA distribution network 300 may include a first power supply 310 (e.g., an ET modulator) coupled to a supply filter 320 through a transmission line 302. The first power supply 310 may receive a signal 314 related to the envelope of the signal to be amplified by the power amplifier. A power amplifier 330 may be coupled to the first power supply 310 through the supply filter 320. The power amplifier 330 may include a driver stage 332 coupled to a power stage 334. A stabilizing circuit 304 (e.g., an RC snubber) may be coupled to the transmission line 302 before the supply filter 320. Although not shown, additional supply filters and power amplifiers may also be present (such as those in FIG. 2.) For example, other low-band, mid-band and/or high-band components may be present. These other components are omitted from the drawing to facilitate explanation of novel aspects of the present disclosure.

According to aspects of the present disclosure, the supply filter 320 may include a fixed power amplifier supply bypass capacitor 324 coupled between ground and a node connecting the first power supply 310 to the power stage 334. The supply filter 320 may further include a circuit 350 and a driver amplifier bypass capacitor 322 (e.g., a programmable bypass capacitor) coupled between ground and a node connecting the first power supply 310 to the driver stage 332. The circuit 350 may include a first switch 352 for coupling/decoupling the power amplifier 330 to/from the first power supply 310. According to an aspect, a series resistance of the first switch 352 may stabilize resistance for the first power supply 310, the driver stage 332, and the power stage 334. For example, the first switch 352 may provide stabilization resistance for a power stage-driver stage loop. The circuit 350 may further include a variable capacitor 354.

According to the present disclosure, the first switch 352 may be included along a driver stage path 340. For example, the driver stage path 340 may be a portion of the transmission line 302 that couples the driver stage 332 to the first power supply 310. In operation, the first switch 352 may couple/decouple the driver stage 332 to/from the first power supply 310. For example, the driver stage 332 may be decoupled from the transmission line 302 when the driver stage 332 is OFF, and coupled to the transmission line 302 when the driver stage 332 is ON. The driver stage 332 may be off when the driver stage 332 is part of a mid-band or high-band power amplifier, for example, and the low-band components are in use but the mid-band and high-band components are not.

According to another aspect, the first switch 352 may be included along a power stage path 342. For example, the power stage path 342 may be a portion of the transmission line 302 that couples the power stage 334 to the first power supply 310. In operation, the first switch 352 may couple/decouple the power stage 334 to/from the first power supply 310. For example, the power stage 334 may be decoupled from the transmission line 302 when the power stage 334 is OFF, and coupled to the transmission line 302 when the power stage 334 is ON.

According to additional aspects of the present disclosure, a switch may be included in both the driver stage path 340 and the power stage path 342. For example, the first switch 352 may be included in either the driver stage path 340 or the power stage path 342. An additional switch 353 may be included in either the driver stage path 340 or the power stage path 342 that does not include the first switch 352. Alternatively, a single switch (e.g., 352) may be implemented such that it couples the first power supply 310 to the driver stage 332 when it is closed, and it couples the first power supply 310 to the power stage 334 when it is open. In this way, either or both of the driver stage 332 and/or the power stage 334 may be coupled/decoupled to/from the first power supply 310.

According to an aspect of the present disclosure, by coupling/decoupling the driver stage 332 and/or the power stage 334 to/from the transmission line 302, a capacitive load of the supply filter 320 after the first switch 352 is also coupled/decoupled to/from the transmission line 302. This allows for improved performance of both the first power supply 310 and the supply filter 320. That is, the first power supply 310 does not see the capacitance when the driver stage 332 is not in use, while the driver stage 332 benefits from the additional capacitance when in use.

According to another aspect of the present disclosure, the power amplifier 330 may include any combination of at least one of a low-band power amplifier, a mid-band power amplifier, or a high-band power amplifier. For example, the power supply-to-PA distribution network 370 may include at least one of the low-band power amplifier, the mid-band power amplifier, or the high-band power amplifier. Additionally, the power supply-to-PA distribution network 370 may include two low-band power amplifiers and one mid-band power amplifier, one low-band power amplifier and two mid-band power amplifiers, one mid-band power amplifier and two high-band power amplifiers, one low-band power amplifier and one high-band power amplifier, or any other similar combination. Of course these combinations are exemplary only, and other combinations are possible, including combinations of more or less than three power amplifiers.

According to an aspect, when at least one of a driver stage and/or power stage of a low-band power amplifier, mid-band power amplifier, or high-band power amplifier is decoupled from the transmission line 302, at least one other driver stage and/or power stage of another low-band power amplifier, mid-band power amplifier, or high-band power amplifier may be coupled to the transmission line 302. For example, in a power supply-to-PA distribution network with one low-band power amplifier, one mid-band power amplifier, and one high-band power, if a driver stage of the low-band amplifier is decoupled from the transmission line 302, then at least one driver stage of the mid-band or high-band power amplifier may be coupled to the transmission line 302. In this way, at least one power amplifier may always be coupled to the transmission line. According to an aspect, all of the power amplifiers may be decoupled at the same time.

Referring to FIG. 3B, a power supply-to-PA distribution network 370 may include all the features of the power supply-to-PA distribution network 300 of FIG. 3A. For example, the power supply-to-PA distribution network 370 may include the first power supply 310 coupled to the supply filter 320 through the transmission line 302. The first power supply 310 may receive a signal 314 related to the envelope of the signal to be amplified by the power amplifier. The stabilizing circuit 304 may also be coupled to the first power supply 310 before the supply filter. The power amplifier 330 may be coupled to the first power supply 310 through the supply filter 320. The supply filter 320 may include the fixed power amplifier supply bypass capacitor 324, the driver amplifier bypass capacitor 322, and the circuit 350. The circuit 350 may include the first switch 352 and the variable capacitor 354. As with FIG. 3B, additional supply filters and power amplifiers may also be present (such as those in FIG. 2.)

According to aspects of the present disclosure, the power supply-to-PA distribution network 370 may further include a second power supply 312 (Vbatt). For example, the second power supply 312 may be a voltage source (e.g., a battery, etc.) The second power supply 312 may be coupled to the supply filter 320 through the transmission line 302. The power amplifier 330 may be coupled to the second power supply 312 through the supply filter 320. The second power supply 312 may selectively power the power amplifier 330 instead of the first power supply 310. In cases when the second power supply 312 is a battery, the constant supply voltage may provide benefits such as improving noise and linearity for wide bandwidth signals

According to aspects of the present disclosure, the circuit 350 may include a second switch 356 along the driver stage path 340 for coupling/decoupling the second power supply 312 to/from the power amplifier 330. For example, the second switch 356 may decouple the driver stage 332 from the second power supply 312 when the driver stage 332 is OFF or when the first power supply 310 powers the driver stage 332. In addition, the second switch 356 may couple the driver stage 332 to the second power supply 312 when the driver stage 332 is ON and the first power supply 310 is not powering the driver stage 332. The first switch 352 and the second switch 356 may alternate between open and closed positions to determine whether the first power supply 310 or the second power supply 312 powers the power amplifier 330 when the driver stage 332 is ON.

According to another aspect of the present disclosure, the second switch 356 may be included in the power stage path 342 and the first switch 352 may be included in the driver stage path 340. Alternatively, a third switch 357 may be included on the power stage path 342, the first switch 352 may be included on the driver stage path 340, and the second switch 356 may be included in either the driver stage path 340 or the power stage path 342. In this way, either or both of the driver stage 332 and/or the power stage 334 may be coupled/decoupled to/from the first power supply 310 and/or the second power supply 312.

According to an aspect, a series resistance of the first switch 352, the second switch 356, and/or the third switch (not shown) may stabilize resistance for the first power supply 310, the driver stage 332, and the power stage 334. For example, the first switch 352, the second switch 356, and/or the third switch (not shown) may provide stabilization resistance for a power stage-driver stage loop.

According to an aspect, by coupling/decoupling the driver stage 332 and/or the power stage 334 to/from the transmission line 302, a capacitive load of the supply filter 320 after the first switch 352, the second switch 356, and/or the third switch (not shown) is also coupled/decoupled to/from the transmission line 302. This allows for improved performance of both the first power supply 310 and the supply filter 320.

According to additional aspects, the power supply-to-PA distribution network 370 may completely disconnect the driver stage 332 from the transmission line 302 and the first power supply 310. For example, the second switch 356 may supply the driver stage 332 with a constant supply voltage from the second power supply 312. This is useful for improving noise and linearity of wide bandwidth signals.

According to another aspect of the present disclosure, all capacitive loads for on-mode functionality are added after the first switch 352. For example, a resistor-capacitor (RC) element, such as a noise notch 326 (e.g., a notch filter) and/or the driver amplifier bypass capacitor 322, may be included after the first switch 352. The driver amplifier bypass capacitor 322 configures the supply filter 320 based on a number of power amplifiers in the power supply-to-PA distribution network 370. The supply filter is also configured based on a user equipment's (e.g., smartphone, tablet, laptop, etc.) parasitic compensation for increasing power amplifier stability under mismatch.

Because full disconnection of off-mode power amplifiers from the modulator distribution line may make current management complex and expensive, the proposed solution is advantageous by disconnecting a specific driver stage and/or power stage of the power amplifier using at least one series switch. Disconnecting the driver stage and/or power stage is possible due to limited current needed when the driver stage and/or power stage are OFF. Additionally, a series switch resistance may stabilize resistance for the envelope tracking driver stage and the power stage modulation. For example, the switch may provide stabilization resistance for a power stage-driver stage loop. Another advantage is that the proposed solution allows for capacitive load reduction of an envelope modulator while also resolving challenges in RF power amplifiers, such as improving stability and noise, while allowing high performance and high modulation bandwidth.

Additional advantages include keeping the modulator capacitive load as small as possible, improving high-bandwidth ET functionality, reducing the number of modulators in a platform, improving noise and sensitivity performance, and improving PA stability and performance. For example, the proposed solution allows for custom supply filtering based on card parasitics, and also allows for linearity/power-added efficiency (PAE) tradeoff.

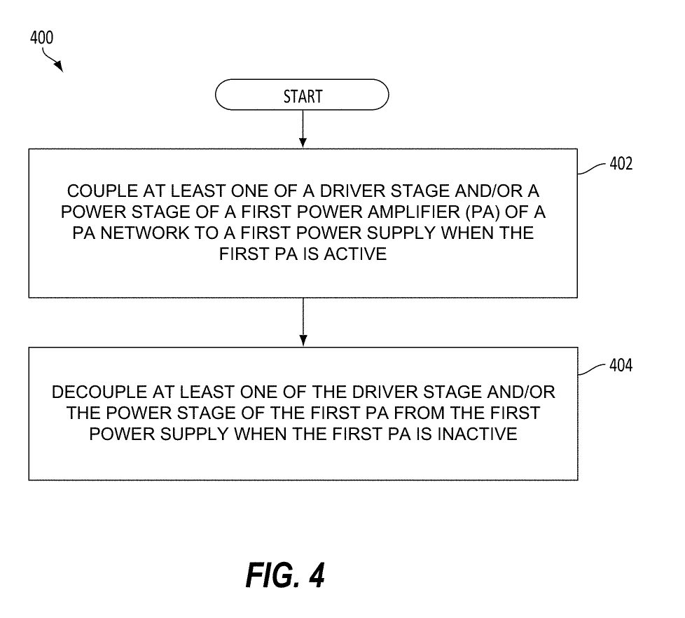

FIG. 4 is a process flow diagram illustrating a method 400 of supplying power to a power supply to power amplifier (PA) distribution network according to aspects of the present disclosure. In block 402, at least one of a driver stage and/or a power stage of a first power amplifier of a PA network is coupled to a first power supply when the first power amplifier is active. For example, referring to FIGS. 3A and 3B, when the power amplifier 330 is active, the driver stage 332 may be coupled to the first power supply 310 through the driver stage path 340, and the power stage 334 may be coupled to the first power supply 310 through the power stage path 342. Either one or both of the driver stage path 340 and/or the power stage path 342 may include a switch.

In block 404, at least one of the driver stage and/or the power stage of the first power amplifier is decoupled from the first power supply when the first power amplifier is inactive. For example, referring to FIGS. 3A and 3B, when the power amplifier 330 is inactive, at least one of the driver stage 332 and/or the power stage 334 of the power amplifier 330 may be decoupled from the first power supply 310 through at least one switch. As described above, the first switch 352 may couple/decouple the driver stage 332 to/from the first power supply 310, and another switch may couple/decouple the power stage 334 to/from the first power supply 310.

According to additional aspects of the present disclosure, the power supply-to-PA distribution network 370 of FIG. 3B may further include a second power supply 312. The second power supply 312 may selectively power the power amplifier 330 instead of the first power supply 310. For example, the second switch 356 may supply the driver stage 332 with a constant voltage supply from the second power supply 312. Additionally, as described above, multiple switches may couple/decouple the driver stage 332 and/or power stage 334 to/from the first power supply 310 and/or the second power supply 312.

According to additional aspects, the method 400 may further include selectively coupling the second power supply to the driver stage based on a waveform being transmitted by the first PA. For example, the selective coupling may be based on a waveform type and/or a waveform bandwidth.

In one configuration, a power supply to power amplifier (PA) distribution network may include first means for supplying power and second means for supplying power. In one aspect, the first power supply means may be the first power supply 310, as shown in FIGS. 3A and 3B. In one aspect, the second power supply means may be the second power supply 312, as shown in FIG. 3B. In another aspect, the aforementioned means may be any module or any apparatus or material configured to perform the functions recited by the aforementioned means.

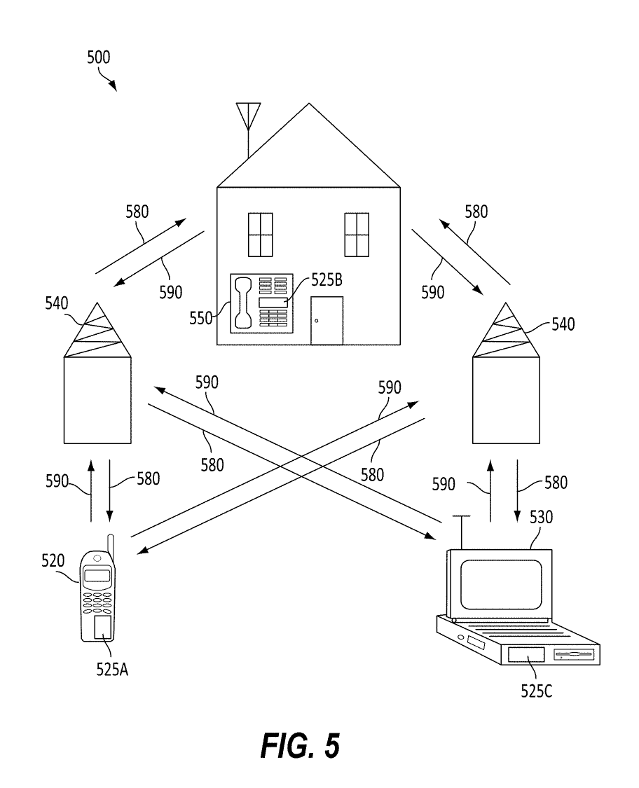

FIG. 5 is a block diagram showing an exemplary wireless communication system 500 in which the power supply-to-PA distribution network may be advantageously employed. For purposes of illustration, FIG. 5 shows three remote units 520, 530, and 550 and two base stations 540. It will be recognized that wireless communication systems may have many more remote units and base stations. Remote units 520, 530, and 550 include IC devices 525A, 525C, and 525B that include the disclosed power supply-to-PA distribution network. It will be recognized that other devices may also include the disclosed power supply-to-PA distribution network, such as the base stations, switching devices, and network equipment. FIG. 5 shows forward link signals 580 from the base station 540 to the remote units 520, 530, and 550 and reverse link signals 590 from the remote units 520, 530, and 550 to base station 540.

In FIG. 5, remote unit 520 is shown as a mobile telephone, remote unit 530 is shown as a portable computer, and remote unit 550 is shown as a fixed location remote unit in a wireless local loop system. For example, a remote unit may be a mobile phone, a hand-held personal communication systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieve data or computer instructions, or combinations thereof. Although FIG. 5 illustrates remote units according to the aspects of the disclosure, the disclosure is not limited to these exemplary illustrated units. Aspects of the disclosure may be suitably employed in many devices, which include the disclosed power supply-to-PA distribution network.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), and Blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A power supply to power amplifier (PA) distribution network, comprising:
a first power supply; and
at least one power amplifier coupled to the first power supply, the at least one power amplifier comprising a driver stage and a power stage, the at least one power amplifier coupled to the first power supply via a first switch.

2. The network of claim 1, in which the driver stage is coupled to the first power supply via the first switch.

3. The network of claim 1, in which the power stage is coupled to the first power supply via the first switch.

4. The network of claim 1, in which the driver stage is coupled to the first power supply via the first switch, and the power stage is coupled to the first power supply via a second switch.

5. The network of claim 1, further comprising a second power supply coupled to the driver stage of the at least one power amplifier via a third switch.

6. The network of claim 1, in which the first power supply comprises an envelope tracking modulator.

7. The network of claim 1, in which the power stage is directly coupled to the first power supply.

8. The network of claim 1, in which the first switch provides a stabilization resistance for a power stage-driver stage loop.

9. The network of claim 1, in which a first of the at least one power amplifier comprises a low-band power amplifier, a second of the at least one power amplifier comprises a mid-band power amplifier, and a third of the at least one power amplifier comprises a high-band power amplifier.

10. The network of claim 1, further comprising a programmable bypass capacitor between the driver stage and the first switch.

11. The network of claim 1, further comprising at least one of a snubber and/or a notch filter between the driver stage and the first switch.

12. A method of supplying power to a power amplifier (PA) network, comprising:
coupling at least one of a driver stage and/or a power stage of a first PA of the PA network to a first power supply when the first PA is active; and
decoupling at least one of the driver stage and/or the power stage of the first PA from the first power supply when the first PA is inactive.

13. The method of claim 12, further comprising selectively activating the first PA of the PA network when other PAs of the PA network are off.

14. The method of claim 12, further comprising:
selectively coupling a second power supply to the driver stage based at least in part on a waveform being transmitted by the first PA.

15. The method of claim 14, in which selectively coupling is based at least in part on at least one of a waveform type and/or a waveform bandwidth.

16. A power supply to power amplifier (PA) distribution network, comprising:
first means for supplying power; and
at least one power amplifier coupled to the first means for supplying power, the at least one power amplifier comprising a driver stage and a power stage, the at least one power amplifier coupled to the first means for supplying power via a first switch.

17. The network of claim 16, in which the driver stage is coupled to the first means for supplying power supply via the first switch.

18. The network of claim 16, in which the power stage is coupled to the first means for supplying power via the first switch.

19. The network of claim 16, in which the driver stage is coupled to the first means for supplying power via the first switch, and the power stage is coupled to the first means for supplying power via a second switch.

20. The network of claim 16, further comprising a second means for supplying power coupled to the driver stage of the at least one power amplifier via a third switch.
